(19) United States
(12) Patent Application Publication
(10) Pub. No.: US 2016/0294306 A1
(43) Pub. Date: Oct. 6, 2016

(54) PIEZOELECTRIC DRIVING DEVICE, ROBOT AND PUMP

(71) Applicant: Seiko Epson Corporation, Tokyo (JP)

(72) Inventor: Tomokazu KOBAYASHI, Shiojiri (JP)

(21) Appl. No.: 15/082,355

(22) Filed: Mar. 28, 2016

(30) Foreign Application Priority Data
Mar. 30, 2015 (JP) 2015-068029

(51) Int. Cl. H02N 2/00; F04B 43/12; B25J 15/02; H01L 41/18

(52) U.S. Cl. CPC H02N 2/001; H01L 41/18; F04B 43/1223; B25J 15/0253

(57) ABSTRACT

A piezoelectric driving device includes a piezoelectric element, which has a first electrode layer, a piezoelectric body layer that is provided above the first electrode layer, and a second electrode layer that is provided above the piezoelectric body layer, and a vibration plate on which the piezoelectric element is provided, and the piezoelectric body layer is a complex oxide that has a perovskite type crystalline structure that includes sodium, potassium and niobium.

### BACKGROUND

1. Technical Field

The present invention relates to a piezoelectric driving device, a robot and a pump.

2. Related Art

Piezoelectric actuators (piezoelectric driving devices) that drive a target driving body by causing a piezoelectric body to vibrate, are used in various fields due to the facts that magnets and coils are not required and that miniaturization thereof is easy (for example, refer to JP-A-2004-320979). A piezoelectric driving device that is disclosed in JP-A-2004-320979 has a configuration that causes a rotating body to rotate using a piezoelectric element (a vibrating body), which includes a piezoelectric material such as lead zirconate titanate (PZT).

The application of piezoelectric driving elements is expected in a wide variety of fields, but since highly toxic metals such as lead are included in piezoelectric materials, for example, an appropriate design is required in a case of use in medical equipment of an implant. In addition, if the disposal of piezoelectric driving devices is taken into consideration, in a case of including a large amount of a highly toxic metal, the possibility of being subject to waste matter restrictions, or the like, arises, and therefore, device management is made more difficult.

Meanwhile, KNN-based (potassium sodium niobate-based) piezoelectric materials have been considered for the fact that such materials do not include lead, and therefore, it is difficult for problems with toxicity to arise, and that compatibility with organisms and the environment is easy. However, in KNN-based piezoelectric materials, it is difficult to realize piezoelectric characteristics that are sufficient enough to surpass those of PZT-based piezoelectric materials.

The research of the present inventors has shown that KNN-based piezoelectric materials can exhibit more favorable piezoelectric characteristics to those of PZT-based piezoelectric materials if the conditions, such as a driving mode and the structure of the element, are chosen. In particular, in a case of a structure that is adopted in a piezoelectric driving device such as an ultrasonic wave motor, or the like, it was understood that it is possible to draw out characteristics that are more favorable than those of PZT-based piezoelectric materials in KNN-based piezoelectric materials.

### SUMMARY

An advantage of some aspects of the invention is to provide a piezoelectric driving device, a robot and a pump, in which the compatibility with organisms and the environment is high, and which have favorable piezoelectric characteristics.

The invention can be realized in the following aspects or application examples.

### Application Example 1

According to this application example, there is provided a piezoelectric driving device including a piezoelectric element that includes a first electrode layer, a piezoelectric body layer which is provided above the first electrode layer, and a second electrode layer which is provided above the piezoelectric body layer, and a vibration plate on which the piezoelectric element is provided, and the piezoelectric body layer is a complex oxide that has a perovskite type crystalline structure that includes sodium, potassium and niobium.

Since the piezoelectric body layer is sodium potassium niobate-based, the piezoelectric driving device according to this application example is highly compatible with organisms and the environment, and has favorable piezoelectric characteristics. As a result of this, it is easy to manage the piezoelectric driving device according to this application example since there are fewer limitations to the applications thereof.

### Application Example 2

In the piezoelectric driving device of the invention, the piezoelectric body layer may have a thickness of 1 μm or more and 15 μm or less.

Since the piezoelectric body layer is a so-called thin film, and is potassium sodium niobate-based, such a piezoelectric driving device has a lower density than that of a case of PZT, and therefore, can exhibit more favorable piezoelectric characteristics.

### Application Example 3

In the piezoelectric driving device of the invention, the complex oxide may include at least one substance selected from manganese, lithium, barium, calcium, strontium, zirconium, titanium, bismuth, tantalum, antimony, iron, cobalt, silver, magnesium, zinc, copper, vanadium, chromium, molybdenum, tungsten, nickel, aluminum, silicon, lanthanum, cerium, praseodymium, neodymium, promethium, samarium, and europium.

Such a piezoelectric driving device can exhibit more favorable piezoelectric characteristics.

### Application Example 4

In the piezoelectric driving device of the invention, in the complex oxide, in a case in which a number of moles of elements other than oxygen is set as 100%, the total number of moles of the elements of sodium, potassium and niobium may be 85% or more.

Such a piezoelectric driving device can exhibit more favorable piezoelectric characteristics.

### Application Example 5

According to this application example, there is provided a robot including a plurality of ring members, a joint section that connects the plurality of ring members, and the piezoelectric driving device according to any one of Application Examples 1 to 4 that causes the plurality of ring members to revolve at the joint section.

Since the robot according to this application example includes a piezoelectric driving device that has a sodium potassium niobate-based piezoelectric body, the robot is highly compatible with organisms and the environment, and has favorable piezoelectric characteristics.

### Application Example 6

According to this application example, there is provided a pump including the piezoelectric driving device according to any one of Application Examples 1 to 4, a tube that transports a liquid, and a plurality of fingers that close the tube as a result of driving of the piezoelectric driving device.

Since the pump according to this application example includes a piezoelectric driving device that has a sodium potassium niobate-based piezoelectric body, the pump is highly compatible with organisms and the environment, and has favorable piezoelectric characteristics.

### BRIEF DESCRIPTION OF THE DRAWINGS

The invention will be described with reference to the accompanying drawings, wherein like numbers reference like elements.

FIGS. 1A and 1B are a plan view and a cross-sectional view that show a schematic configuration of a piezoelectric driving device according to an embodiment.

FIG. 2 is a plan view of a vibration plate.

FIG. 3 is an explanatory diagram that shows an electrical connection state of a piezoelectric vibration device and a driving circuit.

FIG. 4 is an explanatory diagram that shows an example of an action of the piezoelectric vibration device.

FIG. 5 is an explanatory diagram that shows an example of a robot in which a piezoelectric driving device is used.

FIG. 6 is an explanatory diagram of a wrist section of a robot.

FIG. 7 is an explanatory diagram that shows an example of a liquid delivery pump in which a piezoelectric driving device is used.

### DESCRIPTION OF EXEMPLARY EMBODIMENTS

Hereinafter, an embodiment of the invention will be described in detail using the drawings. Additionally, the embodiment that is described below does not unreasonably limit the contents of the invention that are disclosed in the claims. In addition, not necessarily all of the configurations that are described below are essential constituent requirements.

### 1. Piezoelectric Driving Device

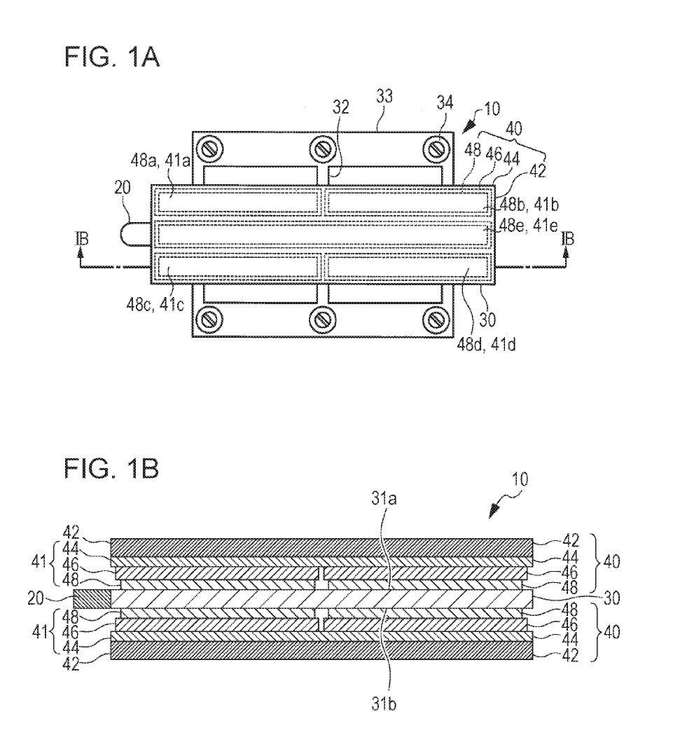

FIG. 1A is a plan view that shows a schematic configuration of a piezoelectric driving device 10 according to the present embodiment, and FIG. 1B is a cross-sectional view along a line IB-IB of FIG. 1A. The piezoelectric driving device 10 includes piezoelectric elements 41a to 41e, which include a piezoelectric body 46, and a plate-shaped vibration plate 30 in which the piezoelectric elements 41a to 41e are disposed. The piezoelectric elements 41a to 41e configure a portion of two piezoelectric vibration bodies 40 that are respectively disposed on both surfaces (a first surface 31a and a second surface 31b) of the vibration plate 30.

### 1-1. Piezoelectric Vibration Body

The piezoelectric vibration body 40 is provided with a substrate 42, a first electrode 44 that is formed on the substrate 42, a piezoelectric body 46 that is formed on the first electrode 44, and a second electrode 48 that is formed on the piezoelectric body 46. The first electrode 44 and the second electrode 48 configure the piezoelectric elements 41a to 41e as a result of the piezoelectric bodies being interposed therebetween. The two piezoelectric vibration bodies 40 are disposed symmetrically with the vibration plate 30 set as the center thereof. In addition, in the present embodiment, the piezoelectric vibration bodies 40 are installed on the vibration plate 30 in a manner in which the substrate 42 and the vibration plate 30 interpose the piezoelectric element (44, 46 and 48) therebetween. Since the two piezoelectric vibration bodies have the same configuration, unless specifically mentioned, the configuration of the piezoelectric vibration body 40 that is on the lower side of the vibration plate 30 will be described below.

The substrate 42 of the piezoelectric vibration body 40 is used as a substrate for forming the first electrode 44, the piezoelectric body 46 and the second electrode 48 using a film formation process. In addition, the substrate 42 has a function as a vibration plate that performs mechanical vibration. For example, it is possible to form the substrate 42 using Si, Al₂O₃, ZrO₂, or the like.

The first electrode 44 is formed as a single continuous conductive body layer that is formed on the substrate 42. Meanwhile, the second electrode 48 is partitioned into five conductive body layers 48a to 48e (also referred to as “second electrodes 48a to 48e”). The second electrode 48e that is in the center is formed in an oblong form that spans substantially the entirety of the substrate 42 in a longitudinal direction at the center of a width direction of the substrate 42. The other four second electrodes 48a, 48b, 48c and 48d have the same planar form, and are formed in the positions of the four corners of the substrate 42. In the example of FIGS. 1A and 1B, the first electrode 44 and the second electrode 48 both have oblong planar forms.

For example, the first electrode 44 and the second electrode 48 are thin films that are formed using sputtering. As the material of the first electrode 44 and the second electrode 48, it is possible to use an arbitrary conductive material such as Al (aluminum), Ni (nickel), Au (gold), Pt (platinum), Ir (iridium), or a conductive oxide. In addition, the first electrode 44 and/or the second electrode 48 may be a laminated body of a plurality of layers.

In addition, in place of configuring the first electrode 44 as a single continuous conductive body layer, the first electrode 44 may be partitioned into five conductive body layers that have the same planar forms as the second electrodes 48a to 48e in a practical sense. Additionally, the illustration of wiring (or alternatively, a wiring layer or an insulation layer) for electrically connecting the second electrodes 48a to 48e, and wiring (or alternatively, a wiring layer or an insulation layer) for electrically connecting the first electrode 44, the second electrodes 48a to 48e and the driving circuit, is omitted from FIGS. 1A and 1B.

The piezoelectric body 46 is formed as five piezoelectric body layers that have the same planar forms as the second electrodes 48a to 48e in a practical sense. In place of this, the piezoelectric body 46 may be formed as a single continuous piezoelectric body layer that has the same planar form as the first electrode 44 in a practical sense. The five piezoelectric elements 41a to 41e (FIG. 1A) are configured by the laminated structure of the first electrode 44, the piezoelectric body 46 and the second electrodes 48a to 48e.

For example, the piezoelectric body 46 is formed using a sol gel technique or a sputtering technique. The material of the piezoelectric body 46 will be described in detail later, but is a ceramic in which an ABO₃ type perovskite type crystalline structure is adopted.

### 1-2. Vibration Plate

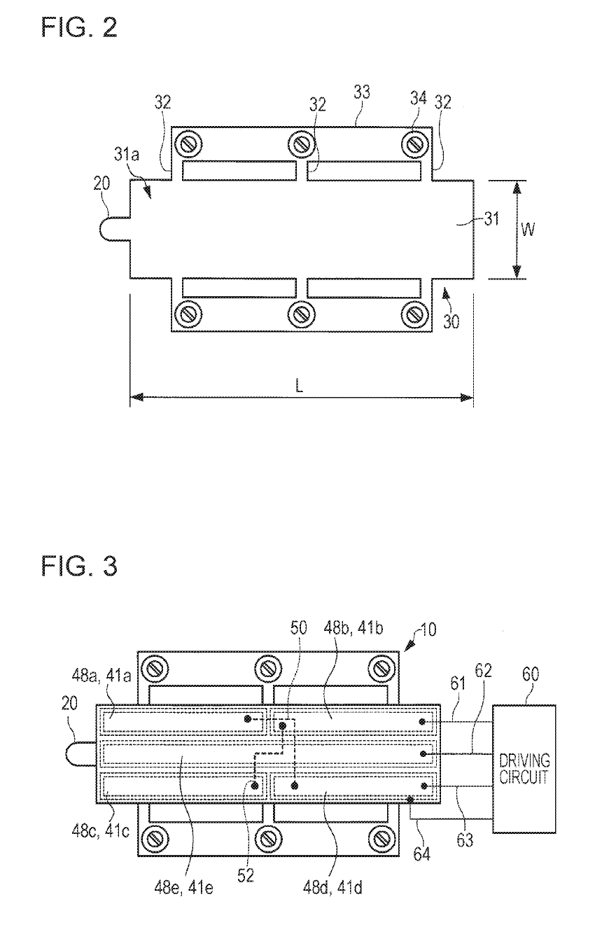

FIG. 2 is a plan view of the vibration plate 30. The vibration plate 30 includes a vibration body section 31, which is an oblong plate material, connection sections 32, three of which respectively extend from the left and right sides of a long edge of the vibration body section 31, and two attachment sections 33 that are respectively connected to the three left and right side connection sections 32. Additionally, the attachment sections 33 are used in order to attach the piezoelectric driving device 10 to other members using screws 34.

The piezoelectric vibration bodies 40 (FIGS. 1A and 1B) are respectively bonded to the upper surface (the first surface 31a) and the lower surface (the second surface 31b) of the vibration body section 31 using an adhesive.

A ratio of the length L and the width W of the vibration body section 31 is preferably L:W=approximately 7:2. This ratio is a preferable value for performing ultrasonic wave vibration (to be described later), in which the vibration body section 31 bends to the left and right along the surface thereof. For example, it is possible to set the length L of the vibration body section 31 to a range of 3.5 mm or more and 30 mm or less, and for example, it is possible to set the width W thereof to a range of 1 mm or more and 8 mm or less. Additionally, in order for the vibration body section 31 to perform ultrasonic wave vibration, it is preferable that the length L be 50 mm or less.

For example, it is possible to set the thickness of the vibration body section 31 (the thickness of the vibration plate 30) to a range of 50 μm or more and 700 μm or less. If the thickness of the vibration body section 31 is set to be 50 μm or more, a vibration body section with sufficient rigidity to support the piezoelectric vibration body 40 is obtained. In addition, if the thickness of the vibration body section 31 is set to be 700 μm or less, it is possible to generate a sufficiently large deformation depending on the deformation of the piezoelectric vibration body 40.

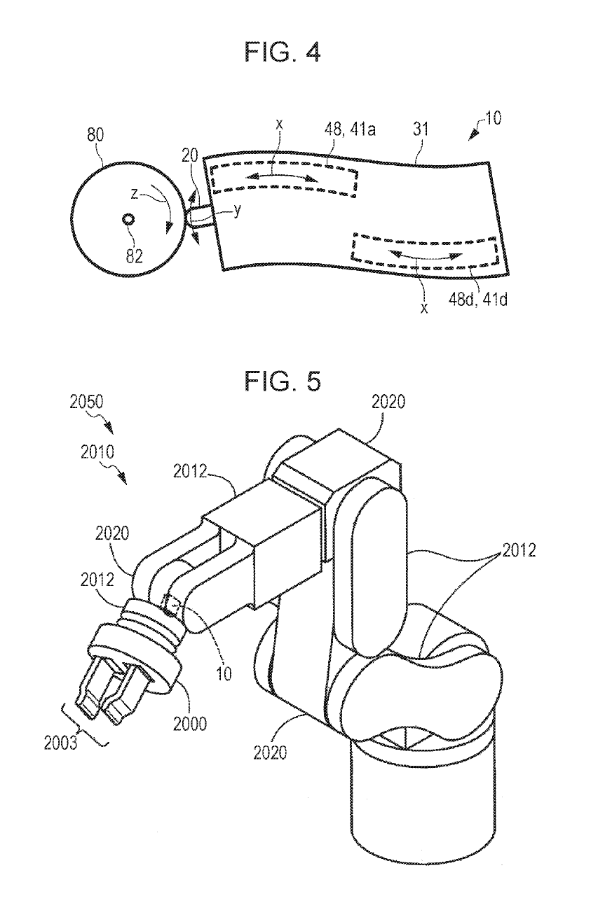

The vibration plate 30 includes a protrusion section 20 (also referred to as a “contact section” or an “action section”) that protrudes from a short edge of the vibration plate 30. The protrusion section 20 is a portion for applying a force to at target driving body by coming into contact with the target driving body (refer to FIG. 4).

### 1-3. Electrical Connection State

FIG. 3 is an explanatory diagram that shows an electrical connection state of the piezoelectric driving device 10 and a driving circuit 60. Among the five second electrodes 48a to 48e, a pair of second electrodes 48a and 48d, which are diagonally opposite one another, are electrically connected via wiring 50, and the other pair of second electrodes 48b and 48c, which are also diagonally opposite one another, are electrically connected via wiring 52. The pieces of wiring 50 and 52 may be formed using a film formation process, or may be realized by wire-form wiring. The three second electrodes 48b, 48e and 48d, which are on the right side in FIG. 3, and the first electrode 44 (refer to FIGS. 1A and 1B) are electrically connected to the driving circuit 60 via pieces of wiring 61, 62, 63 and 64.

The driving circuit 60 causes ultrasonic wave vibrations in the piezoelectric driving device 10 as a result of an AC voltage or a pulsating voltage that changes periodically between the pair of second electrodes 48a and 48d, and the first electrode 44, and thereby, is capable of causing a rotor (a target driving body), which comes into contact with the protrusion section 20, to rotate in a predetermined rotational direction. In this instance, the term “pulsating voltage” refers to a voltage in which DC offsetting has been added to an AC voltage, and the orientation of such a voltage (the electric field thereof) is a direction that runs from one electrode toward another electrode.

In addition, for example, it is possible to cause the rotor, which comes into contact with the protrusion section 20, to rotate in a reverse direction by applying an AC voltage or a pulsating voltage between the other pair of second electrodes 48b and 48c, and the first electrode 44. Such voltage application is performed simultaneously in the two piezoelectric vibration bodies 40 that are provided on both surfaces of the vibration plate 30. Additionally, illustration of the wiring (or alternatively, a wiring layer or an insulation layer) that configures the pieces of wiring 50, 52, 61, 62, 63 and 64 that are shown in FIG. 3, is omitted from FIGS. 1A and 1B.

### 1-4. Actions

FIG. 4 is an explanatory diagram that shows an example of an action of the piezoelectric driving device 10. The protrusion section 20 of the piezoelectric driving device 10 comes into contact with the outer periphery of a rotor 80 as the target driving body. In the example that is shown in FIG. 4, the driving circuit 60 (FIG. 3) applies an AC voltage or a pulsating voltage between the pair of second electrodes 48a and 48d, and the first electrode 44, and the piezoelectric elements 41a and 41d expand and contract in the directions of the arrows x in FIG. 4. According to this extension, the vibration body section 31 of the piezoelectric driving device 10 deforms in a meandering form (an S-shaped form) by bending within a plane of the vibration body section 31, and a leading end of the protrusion section 20 performs a reciprocating motion or an elliptical motion with the orientation of the arrow y. As a result of this, the rotor 80 rotates in a predetermined direction z (in a clockwise direction in FIG. 4) around a center 82 thereof.

The three connection sections 32 (FIG. 2) of the vibration plate 30 that is described in FIG. 2 are provided in positions of knuckles of the vibrations of such a vibration body section 31. Additionally, in a case in which the driving circuit 60 applies an AC voltage or a pulsating voltage between the other pair of second electrodes 48b and 48c, and the first electrode 44, the rotor 80 rotates in the reverse direction. Additionally, if the same voltage as that of the pair of second electrodes 48a and 48d (or the other pair of second electrodes 48b and 48c) is applied to the central second electrode 48e, since the piezoelectric driving device 10 expands and contracts in a longitudinal direction, it is possible to make a force that is applied to the rotor 80 from the protrusion section 20 greater.

### 1-5. Piezoelectric Body Layer

The above-mentioned five respective piezoelectric elements 41a to 41e (FIG. 1A) can be considered as being configured by a first electrode layer (the first electrode 44), a piezoelectric body layer (the piezoelectric body 46) that is provided above the first electrode layer, and a second electrode layer (the second electrode 48) that is provided above the piezoelectric body layer. Further, the piezoelectric driving device 10 is configured as a result of each of the respective piezoelectric elements 41a to 41e (FIG. 1A) being provided on the vibration plate 30.

Additionally, in the present specification, for example, in a case in which the term “above” is used to mean that “a specific component (hereinafter, referred to as “B”) is “above” another specific component (hereinafter, referred to as or the like, the term “above” is used to include a case in which B is directly above A, and a case in which B is above A through another component.

The piezoelectric body 46 that configures the piezoelectric body layer is a ceramic (a complex oxide) in which an ABO₃ type perovskite type crystalline structure is adopted, and includes sodium, potassium and niobium as metals of the A site and a B site. That is, the piezoelectric body 46 is a complex oxide that has either the same or a similar structure to a solid solution (sodium potassium niobate (Na_{0.5}K_{0.5}NbO₃)) of sodium niobate (NaNbO₃) and potassium niobate (KNbO₃), and in which other elements are arbitrarily substituted, and/or incorporated in a lattice at an A site and/or a B site of a perovskite type crystalline structure. That is, the piezoelectric body 46 of the piezoelectric body layer of the present embodiment is a so-called KNN (potassium (K), sodium (Na), and niobium (Nb))-based piezoelectric material.

In addition to potassium (K), sodium (Na) and niobate (Nb), the piezoelectric body layer of the present embodiment may include at least one substance selected from manganese (Mn), lithium (Li), barium (Ba), calcium (Ca), strontium (Sr), zirconium (Zr), titanium (Ti), bismuth (Bi), tantalum (Ta), antimony (Sb), iron (Fe), cobalt (Co), silver (Ag), magnesium (Mg), zinc (Zn), copper (Cu), vanadium (V), chromium (Cr), molybdenum (Mo), tungsten (W), nickel (Ni), aluminum (Al), silicon (Si), lanthanum (La), cerium (Ce), praseodymium (Pr), neodymium (Nd), promethium (Pm), samarium (Sm), and europium (Eu).

Among these elements, for example, in a case in which manganese is included, there are cases in which the leakage current characteristics are improved (it is possible to reduce a leakage current), and in a case in which lithium (for example, 0.5% to 6% and preferably 1% to 5%) is included (added as LiNbO₃, for example), there are cases in which the light is used as a sintering aid, and an effect of enhancing the Curie temperature of a piezoelectric body is obtained. In addition, if zirconium (for example, 5% to 8% and preferably 6% to 7%) is incorporated in the form of a zirconate compound (BaZrO₃, ArZrO₃, CaZrO₃, or the like), there are cases in which it is possible to form a rhombohedral or a tetragonal Morphotropic Phase Boundary (MPB), and in such cases, it is possible to enhance a piezoelectric constant. Furthermore, if (Bi, Na)TiO₃ (for example, 0.5% to 3% and preferably 1% to 2%) is added in addition to a zirconate compound, there are cases in which it is possible to change the MPB, and therefore, for example, it is possible to stabilize the temperature characteristics.

In addition, in the piezoelectric body 46 of the piezoelectric body layer, in a case in which a number of moles of elements other than oxygen is set as 100%, the total number of moles of the elements of sodium, potassium and niobium is 75% or more, preferably 80% or more, more preferably 85% or more, still more preferably 87% or more, and particularly preferably 90% or more. If set within such a range, it is possible to add, or improve other properties (for example, electrical characteristics, crystallinity, and the like) while maintaining a favorable property with respect to the fact that it is easy to exhibit the physical properties (the piezoelectric characteristics) of a KNN-based piezoelectric material.

The piezoelectric body 46 of the piezoelectric body layer may be uniform (homogenous) throughout the entire piezoelectric body layer, or may have variations, or the like in the composition thereof. For example, in a case in which the piezoelectric body layer is created using a sol gel technique, if the piezoelectric body layer is created by performing the processes of coating, drying, calcining, and the like a plurality of times, there are cases in which variations in composition arise in a thickness direction of the piezoelectric body layer, but it is possible to sufficiently exhibit the effect to be described later as long as at least the entire piezoelectric body layer has the above-mentioned configuration.

The piezoelectric body layer is disposed between the first electrode layer and the second electrode layer, and can deform (undergo electro-mechanical conversion) as a result of an electric field being applied by the first electrode layer and the second electrode layer. The thickness of the piezoelectric body layer is not particularly limited within a range in which it is possible to obtain a predetermined deformation amount using a predetermined electric field. However, for example, in a case in which the piezoelectric body layer is provided respectively in contact with the first electrode layer and the second electrode layer, the thickness of the piezoelectric body layer is 300 nm or more and 1 mm or less, preferably 0.5 μm or more and 0.5 mm or less, more preferably 1 μm or more and 0.2 mm or less, still more preferably 1 μm or more and 100 μm or less, and particularly preferably 1 μm or more and 10 μm or less. When the thickness of the piezoelectric body layer is of such an extent, it is easy to adjust the piezoelectric body layer so as to have predetermined piezoelectric characteristics at a size at which it is easy to manage the piezoelectric element (the piezoelectric driving device 10). In addition, the reason for the following will be described later, but it is preferable that the thickness of the piezoelectric body layer is of an extent of 1 μm or more and 15 μm or less, or more preferably 1 μm or more and 10 μm or less, since it is possible to further significantly exhibit the piezoelectric characteristics of the piezoelectric body 46, which is a KNN-based piezoelectric material.

In the piezoelectric driving device 10 of the present embodiment, since the piezoelectric body layer (the piezoelectric body 46) does not include lead (is a so-called lead-free piezoelectric body layer), the compatibility with organisms and the environment is high, and therefore, there are fewer limitations, and the like, on the applications thereof, and the management of disposal of the device, and the like is easy. Additionally, since a KNN-based piezoelectric material is adopted in the piezoelectric driving device 10, it is possible to obtain sufficient piezoelectric characteristics. This will be described in detail in the following paragraph.

### 1-6. Characteristics of Piezoelectric Element in Piezoelectric Driving Device

The piezoelectric element is an element that performs electro-mechanical conversion, and can convert electrical energy for driving a piezoelectric driving device into mechanical energy. That is, electrical energy that is input into the piezoelectric element is converted into distortion energy by the piezoelectric element, and becomes mechanical energy as a result. Therefore, in piezoelectric driving devices, more efficient conversion of electrical energy into distortion energy of a piezoelectric element is required.

Furthermore, in the manner mentioned above, an AC voltage or a pulsating voltage is applied to the piezoelectric driving device. That is, (dynamic) electrical energy that changes with time, is input. Therefore, in the piezoelectric driving device, a piezoelectric vibration work rate is important, that is, a piezoelectric driving device in which the piezoelectric vibration work rate is high, can be referred to as a piezoelectric driving device with a high electro-mechanical conversion efficiency.

The piezoelectric vibration work rate in the piezoelectric driving device is dependent upon at least the structure, the spring constant (k), and the mechanical quality coefficient (Qm). In a case in which movement of the piezoelectric driving device is approximated using primary spring vibrations, it is possible to evaluate the piezoelectric vibration work rate by calculating a longitudinal vibration work rate. Therefore, hereinafter, an approximate longitudinal vibration work rate in an object that performs such spring motion will be referred to as a longitudinal vibration work rate (P_{Dynamic}:W) of the piezoelectric driving device.

As represented by Formula (I) below, the longitudinal vibration work rate (P_{Dynamic}:W) is proportional to the product of the driving frequency (freq: Hz), the square of the mechanical quality coefficient (Qm²), the synthetic spring constant ((kₐₗₗ) m/N), and the square of the total displacement amount (u²:m²). That is, the longitudinal vibration work rate (P_{Dynamic}:W) is represented the product of the frequency, the square of the mechanical quality coefficient (Qm²) and the static distortion energy. Additionally, the text in the brackets above shows symbols and units (dimensions).

P_{Dynamic}∝Freq×Qₘ²×½kₐₗₗ×u² (I)

Further, in the manner of the piezoelectric driving device 10 that is shown in FIG. 2 and the like, the vibration plate 30 (abbreviated to “Shim” in the formula) has an oblong form in plan view, the long edge thereof is L (m), the width is W (m), the thickness is tₛₕᵢₘ (m), L:W is 7:2, and the piezoelectric driving device can deform in the manner of Formula (II) below when a voltage to be applied is set as V(V) in a case of having a piezoelectric body 46 (the piezoelectric body layer) with a thickness of t_{Piezo} (m).

$${P}_{Dynamic} ∝ \frac{1}{7} \sqrt{\frac{{E}_{Piezo}}{ρ}} \cdot \frac{{d}_{31}^{2} \cdot {E}_{Piezo}^{2}}{2 \cdot {t}_{Piezo} \cdot {E}_{Piezo} + {t}_{Shim} \cdot {E}_{Shim}} \cdot {Q}_{m}^{2} \cdot L \cdot {V}^{2} \qquad ( II )$$

In Formula (II), E_{Piezo} is the Young's modulus of the piezoelectric body 46 (N/m²) (=Pa), ρ is the density of the piezoelectric body 46 (10³·kg/m³), d₃₁ is the piezoelectric d constant (m/V), Eₛₕᵢₘ is the Young's modulus of the vibration plate 30 (N/m²) (=Pa).

As a result of the investigation of the inventors, it was confirmed that Formula (II) above has a proportional relationship with a measured output value in the piezoelectric driving device 10 that is described above. That is, it was confirmed that if the longitudinal vibration work rate (P_{Dynamic}:W) is large, the output value in the piezoelectric driving device 10 of the present embodiment is more favorable.

In this instance, when Formula (II) is considered, t_{piezo} it can be understood that at least ρ and/or t are small, and therefore, that the longitudinal vibration work rate (P_{Dynamic}) becomes greater as E_{Piezo}, Qm, L, and/or V become larger.

Given that, in the piezoelectric driving device 10 of the present embodiment, a KNN-based piezoelectric material is used. The density of KNN-based piezoelectric materials is low in comparison with other piezoelectric materials. For example, in contrast with the density of a PZT-based piezoelectric material being approximately 7.5 to 8.5 (10³·kg/m³), that of a KNN-based piezoelectric material is approximately half at approximately 4.3 to 4.6 (10³·kg/m³).

Accordingly, in a case in which the other physical property values and dimensional values that are represented in Formula (II) are approximately equivalent for a PZT-based piezoelectric material and a KNN-based piezoelectric material, it can be understood that the KNN-based piezoelectric material is extremely advantageous in terms of the high electro-mechanical conversion efficiency thereof.

In addition, the Young's modulus (the elastic modulus) of the KNN-based piezoelectric material that is used in the piezoelectric driving device 10 of the present embodiment is high in comparison with other piezoelectric materials. For example, in contrast to the Young's modulus of PZT-based piezoelectric materials being approximately 50 to 80 (GPa) that of KNN-based materials is greater at approximately 80 to 120 (GPa). Accordingly, as a result of this fact, in a case in which the other physical property values and dimensional values that are represented in Formula (II) are approximately equivalent for a PZT-based piezoelectric material and a KNN-based piezoelectric material, it can be understood that the KNN-based piezoelectric material is advantageous in terms of the high electro-mechanical conversion efficiency thereof.

Meanwhile, the mechanical quality coefficient Qm is a constant that shows the sharpness of mechanical vibration displacement in the vicinity of a resonance frequency when the piezoelectric body causes resonance vibration. Generally, in a case of using a piezoelectric body in an application of driving with a resonance frequency, if a material with a high Qm is used, a large vibrational amplitude is obtained. However, if the Qm value is large, the width of the frequency of vibrations that causes resonance is narrow, and therefore, it is difficult to handle fluctuations in the resonance frequency due to variations in the structure of the element, the composition of the piezoelectric body, and the like.

That is, in a case in which the Qm value is large, although high piezoelectric characteristics (electro-mechanical conversion rate) can be expected, high accuracy is required through regulation of the frequency of the voltage (the electric field) that is applied and the amplitude, and therefore, there are cases in which it is difficult to obtain the expected characteristics since it is not possible to handle fluctuations in the resonance frequency due to fluctuations in the temperature of an installation environment, or the like.

In addition, in a case in which the thickness of the piezoelectric body layer is comparatively low in the manner of the piezoelectric driving device of the present embodiment (a thin film), even if a piezoelectric material with a large Qm value is used, it is not necessarily easy to perform setting so that the Qm value is as large as a case of a bulk (a thick film) piezoelectric material. In this manner, in a case of a configuration such as that of the piezoelectric driving device 10 of the present embodiment, there are conditions that are of more importance that the size of the Qm value in a bulk piezoelectric material.

The Qm values in bulk KNN-based piezoelectric materials are not necessarily higher than those in PZT-based materials. However, in a case of a configuration such as that of the piezoelectric driving device 10 of the present embodiment, in the manner mentioned above, since there are cases in which a high Qm value results in tuning of the device being difficult, it is not necessary to increase the Qm value to the extent of that of a bulk value, and therefore, when a balance between the size of the piezoelectric characteristics of the device and the ease of adjustment is taken into consideration, it is actually favorable for the Qm value not to be too high. Accordingly, in a configuration such as that of the piezoelectric driving device 10 of the present embodiment, in both KNN-based and PZT-based piezoelectric materials, there is a range of Qm values that are easy to handle. Accordingly, in cases in which either a KNN-based or a PZT-based material is used, rather than maximization of the Qm value, a design that achieves a certain Qm value is used. In this manner, in a case of a structure and configuration such as that of the piezoelectric driving device 10 of the present embodiment, a design that achieves a similar Qm values is used regardless of the type of the piezoelectric material.

When designing so that the Qm value is similar in a case of using a KNN-based piezoelectric material and a case of using a PZT-based piezoelectric material, as represented in Formula (II) above, by using a piezoelectric material in which the density is small, and the Young's modulus is high, it can be understood that a high equivalent value of dynamic strain energy is obtained.

As a result of this, in a configuration such as that of the piezoelectric driving device 10 of the present embodiment, it can be understood that the use of a KNN-based piezoelectric material is at least extremely advantageous in comparison with using a PZT-based piezoelectric material.

Furthermore, when Formula (II) is considered, the thickness t_{Piezo} (m) of the piezoelectric body 46 is a denominator. From this fact, it can be understood that the value of the equivalent value of dynamic strain energy becomes greater as the thickness of the piezoelectric body (the piezoelectric body layer) becomes smaller. Therefore, in the manner mentioned above, it is preferable that the thickness of the piezoelectric body layer is of an extent of 1 μm or more and 15 μm or less, or more preferably 1 μm or more and 10 μm or less since it is possible to further significantly exhibit the piezoelectric characteristics of the piezoelectric body 46, which is a KNN-based piezoelectric material.

Additionally, in comparison with other general piezoelectric materials, in the KNN-based piezoelectric material that is used in the piezoelectric driving device 10 of the present embodiment, the dielectric constant (∈₃₃: −) is comparatively small, and the Curie temperature (Tc: ° C.) is comparatively high. Therefore, there are advantages of the generation of heat during driving of the device being suppressed, and it being easy to adapt to a usage environment at high temperature.

### 2. Embodiment of Apparatus Using Piezoelectric Driving Device

### 2-1. Robot

FIG. 5 is an explanatory diagram that shows an example of a robot 2050 that uses the above-mentioned piezoelectric driving device 10. The robot 2050 includes an arm 2010 (also referred to as an “arm section”) that is provided with a plurality of ring sections 2012 (also referred to as “ring members”), and a plurality of joint sections 2020 that connect the ring sections 2012 in states in which the ring sections 2012 are capable of revolving or bending.

The piezoelectric driving device 10 described above is installed at the respective joint sections 2020, and it is possible to cause the joint sections 2020 to revolve or bend at arbitrary angles using the piezoelectric driving devices 10. A robot hand 2000 is connected to the tip end of the arm 2010.

The robot hand 2000 is provided with a pair of gripping sections 2003. The piezoelectric driving device 10 is also installed in the robot hand 2000, and it is possible to grip an object by opening and closing the gripping sections 2003 using the piezoelectric driving device 10. In addition, the piezoelectric driving device 10 is also provided between the robot hand 2000 and the arm 2010, and it is possible to rotate the robot hand 2000 with respect to the arm 2010 using the piezoelectric driving device 10.

In this manner, it is possible to use the piezoelectric driving device 10, which uses a KNN-based piezoelectric material, in the driving of the robot 2050.

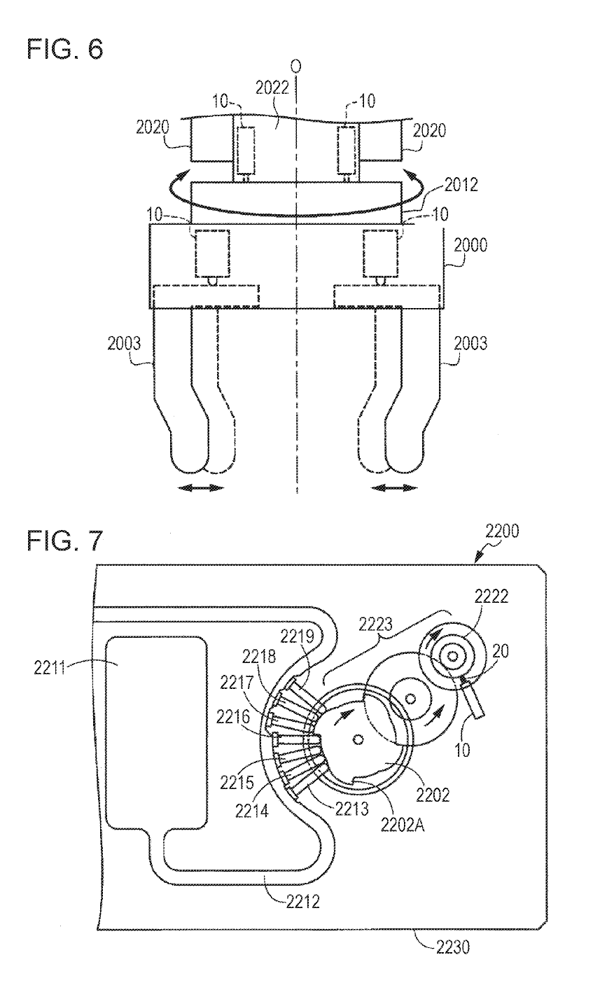

FIG. 6 is an explanatory diagram of a wrist section of the robot 2050 that is shown in FIG. 5. The joint sections 2020 of a wrist interpose a wrist revolution section 2022, and the ring section 2012 of the wrist is attached to the wrist revolution section 2022 so as to be capable of revolving around a central axis O of the wrist revolution section 2022.

The wrist revolution section 2022 is provided with the piezoelectric driving devices 10, and the piezoelectric driving devices 10 cause the ring section 2012 and the robot hand 2000 to revolve around the central axis O. The plurality of gripping sections 2003 are vertically arranged on the robot hand 2000. The base end sections of the gripping sections 2003 are capable moving within the robot hand 2000, and the piezoelectric driving devices 10 are installed in portions of the bases of the gripping sections 2003. Therefore, by moving the piezoelectric driving devices 10, it is possible to grip a target object as a result of the gripping sections 2003 moving.

Additionally, the robot is not limited to a single-armed robot, and it is also possible to apply the piezoelectric driving device 10 to a multi-arm robot in which the number of arms is two or more. In this instance, power lines that supply power to various devices in addition to the piezoelectric driving device 10 such as a torque sensor, a gyrosensor and the like, signal lines that transmit signals, and the like, are included inside the joint section 2020 and the robot hand 2000, and therefore, a significantly large amount of wiring is it is necessary. Accordingly, it is extremely difficult to dispose the wiring inside the joint section 2020 and the robot hand 2000. However, since the above-mentioned piezoelectric driving device 10 of the present embodiment can reduce the driving current beyond that of general driving motors and piezoelectric driving devices of the related art, it is also possible to dispose the wiring in small spaces such as the joint section 2020 (in particular, the joint sections of the tip end of the arm 2010) and the robot hand 2000.

### 2-2. Pump

FIG. 7 is an explanatory diagram that shows an example of a liquid delivery pump 2200 that uses the above-mentioned piezoelectric driving device 10. In the liquid delivery pump 2200, a reservoir 2211, a tube 2212, the piezoelectric driving device 10, a rotor 2222, a deceleration transmission mechanism 2223, a cam 2202, and a plurality of fingers 2213, 2214, 2215, 2216, 2217, 2218 and 2219 are provided in a case 2230. The reservoir 2211 is an accommodation section for accommodating a liquid, which is a transport target. The tube 2212 is a pipe for transporting liquid that is fed out from the reservoir 2211.

The protrusion section 20 of the piezoelectric driving device 10 is provided in a state of pushing against a side surface of the rotor 2222, and the piezoelectric driving device 10 performs rotational driving of the rotor 2222. A rotational force of the rotor 2222 is transmitted to the cam 2202 via the deceleration transmission mechanism 2223. The fingers 2213 to 2219 are members for blocking the tube 2212. When the cam 2202 rotates, the fingers 2213 to 2219 are pushed to an outer side of a radiation direction thereof in order by the protrusion sections 2202A of the cam 2202. The fingers 2213 to 2219 successively block the tube 2212 from an upstream side in a transport direction (a side of the reservoir 2211). As a result of this, the liquid inside the tube 2212 is successively transported to a downstream side. If configured in this manner, it is possible to realize a compact liquid delivery pump 2200 that is capable of delivering extremely small amounts of liquid with high precision.

In this manner, it is possible to use the piezoelectric driving device 10, which uses a KNN-based piezoelectric material, in the driving of the liquid delivery pump 2200.

Additionally, the disposition of each member is not limited to the illustrated dispositions. In addition, a configuration that is not provided with members such as the fingers, and in which balls or the like that are provided on the rotor 2222 block the tube 2212, is also possible. A liquid delivery pump 2200 such as that mentioned above can be applied to a dosing appliance that administers drugs such as insulin to humans, or the like. In this instance, since the driving current is reduced beyond those of piezoelectric driving devices of the related art as a result of using the above-mentioned piezoelectric driving device 10 of the present embodiment, it is possible to suppress power consumption of an a dosing appliance. Accordingly, this is particularly effective in a case in which the dosing appliance is battery driven.

### 3. Working Examples

Hereinafter, the invention will be described on the basis of working examples, but the invention is not limited to these working examples.

### 3-1. Preparation of Piezoelectric Element

### KNN-Based Material

A silicon dioxide film was formed by preparing a silicon single crystal substrate and performing thermal oxidation of the surface thereof. A titanium oxide film was formed on the obtained silicon dioxide film by forming a titanium film with a thickness of 20 nm using a sputtering technique, and performing thermal oxidation thereof. Next, a first electrode (a first electrode layer), which was formed from a platinum film with a thickness of 130 nm, was formed on the titanium oxide film using a sputtering technique.

Thereafter, a piezoelectric body precursor film was formed by coating the product with a sol-gel solution that included KNN and Mn using a spin coating technique. The sol that included KNN and Mn used a substance with a compositional ratio of K:Na:Nb:Mn=40:60:95:5 (molar ratio).

Thereafter, a drying process was performed at 180° C. for three minutes, and after performing a degreasing process at 380° C. for three minutes, calcining was performed at 700° C. for three minutes while introducing oxygen gas using a Rapid Thermal Annealing (RTA) device.

The piezoelectric body layer was obtained by repeating these piezoelectric body film formation processes 13 times. A piezoelectric element including a piezoelectric body layer that was formed from a KNN-based piezoelectric material was obtained by forming a film of Ir with a thickness of approximately 50 nm using a sputtering technique, and forming the second electrode (the second electrode layer) by performing patterning using photolithography. When measured using a scanning electron microscope (SEM), the thickness of the piezoelectric body layer was approximately 1.3 μm. Hereinafter, this piezoelectric element will be referred to as “KNN-1”.

In the same manner, piezoelectric elements including piezoelectric body layers prepared by repeating the piezoelectric body layer formation processes 30, 50 and 100 times were respectively prepared. The thicknesses of the piezoelectric body layers of the respective piezoelectric elements were approximately 3 μm, approximately 5 μm, and approximately 10 μm. Hereinafter, these piezoelectric elements will respectively be referred to as “KNN-3”, “KNN-5” and “KNN-10”.

Meanwhile, a piezoelectric elements provided with a piezoelectric body layers that was formed from a so-called bulk piezoelectric body, was prepared using the following sequence. Na₂CO₃, K₂CO₃ and Nb₂O₅ powder were prepared as starting materials of the main ingredients for obtaining a piezoelectric body layer, and these powders were weighed and added so that the compositional ratio thereof in a dried state was K:Na:Nb:Mn=40:60:95:5 (molar ratio). Thereafter, a raw material mixture was formed by adding pure water and ethanol, and mixing and pulverizing the powder mixture in a ball mill. Furthermore, after drying the raw material mixture, a complex oxide powder containing K, Na and Nb was formed by performing synthesis (pre-calcining) at 700° C. to 1000° C.

Next, granulation was performed by adding a predetermined amount of a binder to the powder, and the product was molded at a predetermined pressure (1000 kg/cm² to 2000 kg/cm²) using a press mold, or the like. Further, the bulk piezoelectric body was formed by degreasing the molded product at 600° C. to 700° C., and calcining at 1000° C. to 1250° C.

Thereafter, a first electrode and a second electrode with thicknesses of approximately 20 μm were formed by polishing the piezoelectric body to a thickness of 300 μm, coating both surfaces thereof with an Ag paste using a screen printing technique, and further calcining at 700° C. for 30 minutes. Meanwhile, a piezoelectric element provided with a piezoelectric body layer that was formed from a bulk piezoelectric body was obtained using the above-mentioned processes. When measured using a scanning electron microscope (SEM), the thickness of the piezoelectric body layer was approximately 300 μm. Hereinafter, this piezoelectric element will be referred to as “KNN-300”.

### PZT-Based Material

Thermal oxidation of a silicon dioxide film formed as an elastic film on a silicon single crystal substrate, was performed. A ZrO₂ layer was formed by sputtering Zr onto the silicon dioxide film, and carrying out an oxidation process in an oxidation furnace. The first electrode (the first electrode layer) was formed on the ZrO₂ layer by laminating platinum and iridium onto the entire surface thereof using a sputtering technique, and a Ti layer was formed on top as an orientation control layer.

Thereafter, a piezoelectric body precursor film was formed by coating the product with a sol-gel solution that included PZT using a spin coating technique. The sol that included PZT used a substance with a compositional ratio of Pb:Zr:Ti=118:52:48 (molar ratio).

Thereafter, a drying process was performed at 180° C. for three minutes, and after performing a degreasing process at 380° C. for three minutes, calcining was performed at 700° C. for three minutes while introducing oxygen gas using a rapid thermal annealing (RTA) device.

The piezoelectric body layer was obtained by repeating these piezoelectric body film formation processes times. A piezoelectric element of a PZT-based piezoelectric material was obtained by forming a film of Ir with a thickness of approximately 50 nm using a sputtering technique, and forming the second electrode (the second electrode layer) by performing patterning using photolithography.

In the same manner, piezoelectric elements including piezoelectric body layers prepared by repeating the piezoelectric body layer formation processes 30, 50 and 100 times were respectively prepared. The thicknesses of the piezoelectric body layers of the respective piezoelectric elements were approximately 3 μm, approximately 5 μm, and approximately 10 μm. Hereinafter, these piezoelectric elements will respectively be referred to as “PZT-3”, “PZT-5” and “PZT-10”.

Meanwhile, with respect to a piezoelectric element provided with a piezoelectric body layer that was formed from a bulk PZT-based piezoelectric body, apart from using PbZrO₃ and TiZrO₃ as the starting materials of the main ingredients for obtaining the piezoelectric body layer, and setting so as to achieve Pb:Zr:Ti=118:52:48 (molar ratio), a piezoelectric element provided with a piezoelectric body layer that was formed from a bulk PZT-based piezoelectric body was obtained in the same manner as the above-mentioned KNN-300. When measured using a scanning electron microscope (SEM), the thickness of the piezoelectric body layer was approximately 300 μm. Hereinafter, this piezoelectric element will be referred to as “PZT-300”.

### 3-2. Evaluation Content

The mechanical quality coefficient Qm was measured using a ratio of the dynamic displacement amount during resonance/the static displacement amount during dissonance, and the results were recorded in Table 1. The Young's modulus E_{piezo} (N/m²) of the piezoelectric body layers was measured using a resonance type elastic measuring instrument, and the results were recorded in Table 1. The piezoelectric d constant d₃₁ (pm/V) of the piezoelectric body layers was measured using a displacement measurement with a cantilever structure, and the results were recorded in Table 1. The density ρ (10³·kg/m³) of the piezoelectric body layers was measured using an X-ray reflectance measurement technique, and the results were recorded in Table 1. The specific dielectric constant ∈₃₃/∈ and the Curie temperature Tc (° C.) of the piezoelectric body layers were measured using a temperature measurement of the dielectric constant, and the results were recorded in Table 1. In addition, the product of d₃₁ and ∈_{Piezo} was calculated as an indicator of the generation force of the piezoelectric element, and the results were recorded in Table 1.

Further, the longitudinal vibration work rate (P_{Dynamic}:W) was calculated using the above-mentioned Formula (II) for the piezoelectric element of each working example, and the results were recorded in Tables 1 and 2. In addition, a ratio of the longitudinal vibration work rate (P_{Dynamic}:W) for KNN-based piezoelectric elements with respect to PZT-based piezoelectric element was recorded in Table 2.

TABLE 1

| | Thickness of | | | | | | | | Longitudinal |
|---|---|---|---|---|---|---|---|---|---|
| | Piezoelectric | | | | | | | | Vibration |
| | Body Layer | d₃₁ | E_{Piezo} | d₃₁*E_{Piezo} | Qm | ρ | ε₃₃/ε₀ | Tc | Work Rate |
| Reagent | μm | pm/V | GPa | C/m2 | — | g/cm³ | — | ° C. | W |
| KNN-1 | 1.3 | 100 | 100 | 10 | 110 | 4.4 | 1300 | 340 | 130.7 |
| PZT-1 | 1.3 | 148 | 75 | 11.1 | 110 | 7.9 | 1780 | 280 | 104.2 |

TABLE 2

| | Thickness of | Longitudinal | Ratio of KNN-based |
|---|---|---|---|
| | Piezoelectric | Vibration | Material to PZT-based |
| | Body Layer | Work Rate | Material |
| Reagent Name | μm | W | — |
| KNN-1 | 1.3 | 130.7 | 1.254 |
| PZT-1 | | 104.2 | |
| KNN-3 | 3.0 | 129.7 | 1.252 |
| PZT-3 | | 103.6 | |
| KNN-5 | 5.0 | 128.5 | 1.249 |
| PZT-5 | | 102.9 | |
| KNN-10 | 10.0 | 125.6 | 1.242 |
| PZT-10 | | 101.1 | |
| KNN-300 | 300.0 | 54.4 | 1.073 |
| PZT-300 | | 50.7 | |

### 3-3. Evaluation Results

Looking at Table 1, in a case in which the Qm values are of the same extent, the value of the product of d₃₁, which is an indicator of the generation power, and ∈_{Piezo} is smaller for the KNN-based piezoelectric element than for the PZT-based piezoelectric element. However, regardless of the fact that the value of the piezoelectric d constant d₃₁ (pm/V) of the KNN-based piezoelectric element is approximately 0.68 times smaller than that of the PZT-based piezoelectric element, it was confirmed that the value of the equivalent value of dynamic strain energy for the KNN-based piezoelectric element shows a value of 1.25 times that of the PZT-based piezoelectric element. It is thought that the reason for this is that the low density ρ and high Young's modulus ∈_{Piezo} of the KNN-based piezoelectric element mainly contribute in Formula (II).

This shows that a KNN-based piezoelectric element exhibits superior piezoelectric characteristics to a PZT-based piezoelectric element in a case of a piezoelectric driving device that can be approximated using Formula (II).

In addition, looking at Table 2, it can be understood that the use of a KNN-based piezoelectric material becomes more advantageous than the use of a PZT-based piezoelectric material as the thickness of the piezoelectric body layer becomes thinner. That is, as the thickness of the piezoelectric body layer gets thinner, the equivalent value of dynamic strain energy itself increases for both PZT-based and KNN-based materials, but it is evident that KNN-based materials have an improvement effect due to the thinning of the thickness of the piezoelectric body layer.

Accordingly, it is evident that the KNN-based piezoelectric material can shown superior characteristics to those of at least the PZT-based piezoelectric material in a thin-film piezoelectric element (for example, the piezoelectric driving device of the above-mentioned embodiment).

In the invention, a portion of the configurations may be omitted, or each embodiment of modification example may combined within a range that includes the features and effects that are disclosed in the present application. The invention includes configurations that are effectively the same as the configurations described in the embodiment (configurations in which the functions, methods and effects are the same, or configurations in which the objects and effects are the same). In addition, the invention includes configurations in which non-essential configurations described in the embodiment are substituted. In addition, the invention includes configurations that exhibit the same functional effects as, and configurations that can achieve the same objects as the configurations described in the embodiment. In addition, the invention includes configurations in which publicly-known technology is added to the configurations described in the embodiment.

The entire disclosure of Japanese Patent Application No. 2015-068029, filed Mar. 30, 2015 is expressly incorporated by reference herein.

What is claimed is:

1. A piezoelectric driving device comprising:
a piezoelectric element that includes a first electrode layer, a piezoelectric body layer which is provided above the first electrode layer, and a second electrode layer which is provided above the piezoelectric body layer; and
a vibration plate on which the piezoelectric element is provided,
wherein the piezoelectric body layer is a complex oxide that has a perovskite type crystalline structure that includes sodium, potassium and niobium.

2. The piezoelectric driving device according to claim 1,
wherein the piezoelectric body layer has a thickness of 1 μm or more and 15 μm or less.

3. The piezoelectric driving device according to claim 1,
wherein the complex oxide includes at least one substance selected from manganese, lithium, barium, calcium, strontium, zirconium, titanium, bismuth, tantalum, antimony, iron, cobalt, silver, magnesium, zinc, copper, vanadium, chromium, molybdenum, tungsten, nickel, aluminum, silicon, lanthanum, cerium, praseodymium, neodymium, promethium, samarium, and europium.

4. The piezoelectric driving device according to claim 1,
wherein, in the complex oxide, in a case in which a number of moles of elements other than oxygen is set as 100%, the total number of moles of the elements of sodium, potassium and niobium is 85% or more.

5. A robot comprising:
a plurality of ring members;
a joint section that connects the plurality of ring members; and
the piezoelectric driving device according to claim 1 that causes the plurality of ring members to revolve at the joint section.

6. A robot comprising:
a plurality of ring members;
a joint section that connects the plurality of ring members; and
the piezoelectric driving device according to claim 2 that causes the plurality of ring members to revolve at the joint section.

7. A robot comprising:
a plurality of ring members;
a joint section that connects the plurality of ring members; and
the piezoelectric driving device according to claim 3 that causes the plurality of ring members to revolve at the joint section.

8. A robot comprising:
a plurality of ring members;
a joint section that connects the plurality of ring members; and
the piezoelectric driving device according to claim 4 that causes the plurality of ring members to revolve at the joint section.

9. A pump comprising:
the piezoelectric driving device according to claim 1;
a tube that transports a liquid; and
a plurality of fingers that close the tube as a result of driving of the piezoelectric driving device.

10. A pump comprising:
the piezoelectric driving device according to claim 2;
a tube that transports a liquid; and
a plurality of fingers that close the tube as a result of driving of the piezoelectric driving device.

11. A pump comprising:
the piezoelectric driving device according to claim 3;
a tube that transports a liquid; and
a plurality of fingers that close the tube as a result of driving of the piezoelectric driving device.

12. A pump comprising:
the piezoelectric driving device according to claim 4;
a tube that transports a liquid; and
a plurality of fingers that close the tube as a result of driving of the piezoelectric driving device.
